(19) United States
(12) Patent Application Publication
(10) Pub. No.: US 2021/0036221 A1
(43) Pub. Date: Feb. 4, 2021

(54) SWITCHING DEVICE AND STORAGE UNIT, AND MEMORY SYSTEM

(71) Applicant: SONY SEMICONDUCTOR SOLUTIONS CORPORATION, KANAGAWA (JP)

(72) Inventors: KAZUHIRO OHBA, TOKYO (JP); HIROAKI SEI, KANAGAWA (JP); SHUICHIRO YASUDA, KANAGAWA (JP)

(21) Appl. No.: 16/975,069

(22) PCT Filed: Mar. 14, 2019
(86) PCT No.: PCT/JP2019/010455

§ 371 Date: Aug. 21, 2020

(30) Foreign Application Priority Data
Apr. 9, 2018 (JP) 2018-074639

(51) Int. Cl. H01L 45/00; H01L 27/24

(52) U.S. Cl. CPC H01L 45/1253; H01L 27/24; H01L 45/065; H01L 45/141

(57) ABSTRACT

A switching device according to an embodiment of the present disclosure includes: a first electrode; a second electrode disposed to be opposed to the first electrode; and a switching layer provided between the first electrode and the second electrode. The switching layer includes at least one chalcogen element selected from sulfur (S), selenium (Se), and tellurium (Te). At least one of the first electrode or the second electrode includes carbon (C) and, as an additive element, at least one of germanium (Ge), phosphorus (P), or arsenic (As).

### TECHNICAL FIELD

The present disclosure relates to a switching device having a chalcogenide layer between electrodes and a storage unit including the switching device, and a memory system.

### BACKGROUND ART

In recent years, a larger capacity has been demanded of a non-volatile memory for data storage typified by a resistive memory, such as a ReRAM (Resistance Random Access Memory) or a PRAM (Phase-Change Random Access Memory) (registered trademark). However, the existing resistive memory using an access transistor is large in floor area per unit cell. Therefore, as compared with, for example, a NAND flash memory or the like, it is not easy to increase the capacity of the resistive memory even if it is scaled down by using the same design rule. Meanwhile, in a case of using a so-called cross-point array structure in which memory devices are disposed at points of intersection (cross-points) between intersecting wiring lines, the floor area per unit cell is smaller, and thus it becomes possible to achieve a larger-capacity.

A cross-point memory cell is provided with a selection device for cell selection (a switching device) in addition to the memory device. To suppress leakage current in a cross-point array, the switching device is demanded to be low in leakage current when it is off and have less variation in switching threshold voltage. To address this, for example, PTL 1 discloses a memory having a switching material layer held between electrodes that are carbon layers.

### CITATION LIST

### Patent Literature

PTL 1: International Publication WO2004/055828

### SUMMARY OF THE INVENTION

In this way, to achieve a larger capacity, in a cross-point memory cell array, a switching device is demanded to be low in leakage current when it is off and have less variation in switching threshold voltage.

It is desirable to provide a switching device that makes it possible to reduce generation of leakage current and variation in switching threshold voltage and a storage unit including the switching device, and a memory system.

A switching device of an embodiment of the present disclosure includes: a first electrode; a second electrode disposed to be opposed to the first electrode; and a switching layer provided between the first electrode and the second electrode. The switching layer includes at least one chalcogen element selected from sulfur (S), selenium (Se), and tellurium (Te). At least one of the first electrode or the second electrode includes carbon (C) and, as an additive element, at least one of germanium (Ge), phosphorus (P), or arsenic (As).

A storage unit of an embodiment of the present disclosure includes a plurality of memory cells. Each memory cell includes a memory device and the above-described switching device according to the embodiment of the present disclosure directly coupled to the memory device.

A memory system of an embodiment of the present disclosure includes a host computer including a processor, a memory including a memory cell array that includes a plurality of memory cells, and a memory controller that performs request control on the memory in accordance with a command from the host computer. The plurality of memory cells each includes a memory device and the above-described switching device of the embodiment of the present disclosure directly coupled to the memory device.

In the switching device and the storage unit, and the memory system of the respective embodiments of the present disclosure, of the first electrode and the second electrode that hold the switching layer including at least one chalcogen element selected from sulfur (S), selenium (Se), and tellurium (Te) between them, at least either one includes carbon (C) and, as an additive element, at least one of germanium (Ge), phosphorus (P), or arsenic (As). Thus, the additive element is diffused in the vicinity of an interface with the switching layer, and an excellent contact interface with the switching layer is formed.

According to the switching device, the storage unit, and the memory system of the respective embodiments of the present disclosure, of the first electrode and the second electrode that hold the switching layer between them, at least either one includes carbon (C) and, as an additive element, at least one of germanium (Ge), phosphorus (P), or arsenic (As); thus, the additive element is diffused in the vicinity of an interface with the switching layer, and an excellent contact interface with the switching layer is formed. Therefore, it becomes possible to reduce the generation of leakage current and the variation in switching threshold voltage.

It is to be noted that the effects described here are not necessarily limitative, and may be any of effects described in the present disclosure.

### BRIEF DESCRIPTION OF DRAWINGS

FIG. 1 is a cross-sectional view of an example of a configuration of a switching device according to an embodiment of the present disclosure.

FIG. 2 is a schematic diagram that illustrates a distribution of a metallic element when voltage is applied to the switching device illustrated in FIG. 1.

FIG. 3 is a diagram illustrating an example of a schematic configuration of a memory cell array according to an embodiment of the present disclosure.

FIG. 4 is a cross-sectional view of an example of a configuration of a memory cell illustrated in FIG. 3.

FIG. 5 is a cross-sectional view of another example of the configuration of the memory cell illustrated in FIG. 3.

FIG. 6 is a cross-sectional view of another example of the configuration of the memory cell illustrated in FIG. 3.

FIG. 7 is a diagram illustrating a schematic configuration of a memory cell array in Modification Example 1 of the present disclosure.

FIG. 8 is a diagram illustrating an example of a schematic configuration of a memory cell array in Modification Example 2 of the present disclosure.

FIG. 9 is a diagram illustrating another example of the schematic configuration of the memory cell array in Modification Example 2 of the present disclosure.

FIG. 10 is a diagram illustrating another example of the schematic configuration of the memory cell array in Modification Example 2 of the present disclosure.

FIG. 11 is a diagram illustrating another example of the schematic configuration of the memory cell array in Modification Example 2 of the present disclosure.

FIG. 12 is a block diagram illustrating a configuration of a data storage system including a memory system of the present disclosure.

FIG. 13 is a characteristic diagram illustrating a relationship between current and voltage in Experiment 1.

FIG. 14 is a characteristic diagram illustrating a relationship among composition ratio of Ge, leakage current, and variation in Experiment 2.

### MODES FOR CARRYING OUT THE INVENTION

In the following, an embodiment of the present disclosure is described in detail with reference to the drawings. The following description is a specific example of the present disclosure, and the present disclosure is not limited to embodiments described below. Furthermore, as for the disposition, dimensions, the dimension ratio, etc. of each component illustrated in the drawings, the present disclosure is not limited to those. It is to be noted that description is given in the following order.

1. Embodiment (An example where a carbon-containing layer including P or As is provided as an electrode in direct contact with a switching layer)

1-1. Configuration of Switching Device

1-2. Configuration of Memory Cell Array

1-3. Workings and Effects

### 2. Modification Examples

2-1. Modification Example 1 (Another example of a memory cell array having a planar structure)

2-2. Modification Example 2 (An example of a memory cell array having a three-dimensional structure)

3. Application Example (A data storage system)

### 4. Examples

### 1. Embodiment

### 1-1. Configuration of Switching Device

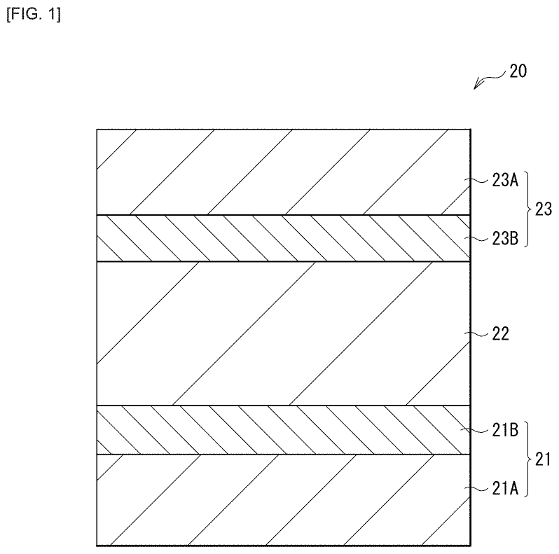

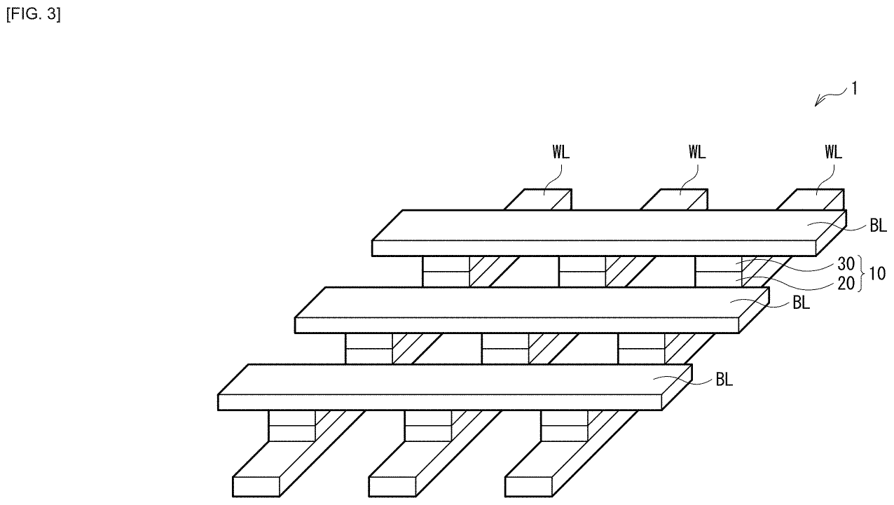

FIG. 1 illustrates an example of a cross-sectional configuration of a switching device (a switching device 20) according to an embodiment of the present disclosure. This switching device 20 is for selectively activating, for example, of a plurality of storage devices provided in a memory cell array 1 having a so-called cross-point array structure illustrated in FIG. 3, any one (a memory device 30; FIG. 3) of the plurality of storage devices. The switching device 20 is coupled in series to the memory device 30 (specifically, a memory layer 31), and includes a lower electrode 21 (a first electrode), a switching layer 22, and an upper electrode 23 (a second electrode) in this order. The switching device 20 of the present embodiment has a configuration in which the lower electrode 21 and the upper electrode 23 are configured as a stack of a metal layer 21A or 23A and a carbon-containing layer 21B or 23B; the carbon-containing layers 21B and 23B are each disposed on the side of the switching layer 22.

The lower electrode 21 has, as described above, a configuration in which the metal layer 21A and the carbon-containing layer 21B are stacked in this order.

The metal layer 21A includes a wiring line material used in a semiconductor process, for example, a material such as tungsten (W), tungsten nitride (WN), titanium nitride (TiN), copper (Cu), aluminum (Al), molybdenum (Mo), tantalum (Ta), tantalum nitride (TaN), or silicide. In a case where the metal layer 21A includes a material prone to ionic conduction in an electric field, such as Cu, a surface of the metal layer 21A including the material such as Cu may be covered with a material less prone to ionic conduction and thermal diffusion, such as W, WN, titanium nitride (TiN), or TaN.

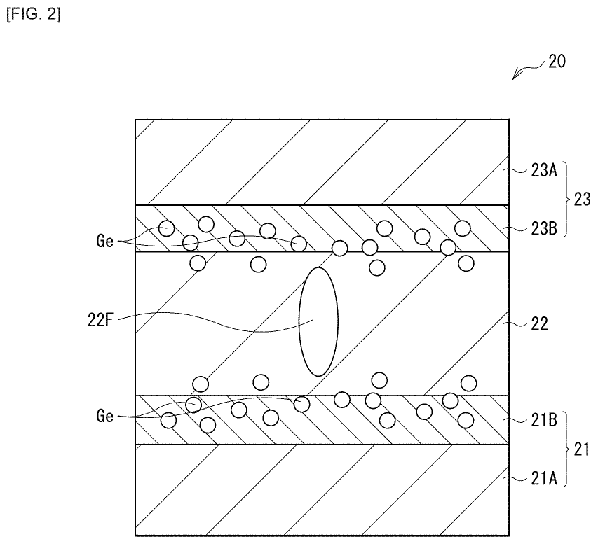

The carbon-containing layer 21B is provided to be in direct contact with the switching layer 22. The carbon-containing layer 21B includes carbon (C) and, as an additive element, at least one of germanium (Ge), phosphorus (P), or arsenic (As). As illustrated in FIG. 2, the additive element added to the carbon-containing layer 21B is diffused in the vicinity of an interface with the switching layer 22 due to thermal diffusion at the time of a process, etc. Thus, an excellent interface is formed between the carbon-containing layer 21B and the switching layer 22, and generation of leakage current and variation in switching threshold voltage are reduced. Furthermore, the diffusion of the additive element in the vicinity of the interface between the carbon-containing layer 21B and the switching layer 22 enhances adhesion between the lower electrode 21 and the switching layer 22.

An added amount of the additive element is preferably that the total amount of all additive elements included in the carbon-containing layer 21B is, for example, from 3 at % to 20 at %. In a case where the added amount is less than 3 at %, it is difficult to achieve the sufficient reductions of leakage current and variation in switching threshold voltage and the enhancement of the adhesion. In a case where the added amount is more than 20 at %, it becomes difficult to obtain excellent selection characteristics, for example, for reasons of a too strong monotectoid reaction in the carbon-containing layer 21B, etc. Furthermore, there is a possibility that delamination is likely to occur.

The film thickness (hereinafter, referred to simply as the thickness) of the carbon-containing layer 21B in a stacking direction is preferably, for example, from 3 nm to 20 nm. In a case where the thickness is less than 3 nm, there is a possibility that it may fail to make enough improvements in generation of leakage current and variation in switching threshold voltage.

The lower electrode 21 is able to be formed together with the metal layer 21A and the carbon-containing layer 21B by means of a well-known film-formation technique, for example, such as physical vapor deposition (Physical Vapor Deposition: PVD) or chemical vapor deposition (Chemical Vapor Deposition: CVD).

The switching layer 22 is changed into a low-resistance state by increasing an applied voltage to a predetermined threshold voltage (a switching threshold voltage) or higher, and is changed into a high-resistance state by decreasing the applied voltage to a voltage lower than the above-described threshold voltage (the switching threshold voltage). That is, the switching layer 22 has a negative differential resistance characteristic, and, when the voltage applied to the switching device 20 exceeds the predetermined threshold voltage (the switching threshold voltage), passes an electric current increased by several figures times. Furthermore, the switching layer 22 has an amorphous structure stably maintained without depending on application of a voltage pulse or a current pulse from a not-illustrated power supply circuit (a pulse applying means) through the lower electrode 21 and the upper electrode 23. It is to be noted that the switching layer 22 does not perform memory operations, such as a conduction path (for example, a filament 22F; see FIG. 2) formed by migration of ions caused by application of voltage being kept even after the applied voltage is erased.

The switching layer 22 includes an element in Group 16 of the Periodic Table, specifically, at least one chalcogen element selected from sulfur (S), selenium (Se), and tellurium (Te). In the switching device 20 having an OTS (Ovonic Threshold Switch) phenomenon, it is necessary for the switching layer 22 to have the amorphous structure stably maintained even when applied with voltage bias for switching; the stabler the amorphous structure is, the more stably the OTS phenomenon is able to be produced. It is preferable that the switching layer 22 include at least one of boron (B) or gallium (Ga) besides the above-described chalcogen element. Furthermore, the switching layer 22 may include an element other than these, for example, germanium (Ge), phosphorus (P), arsenic (As), silicon (Si), carbon (C), oxygen (O), and nitrogen (N) within a level which does not impair effects of the present disclosure.

The thickness of the switching layer 22 is preferably, for example, from 5 nm to 50 nm. The switching layer 22 is able to be formed by means of a well-known film-formation technique, for example, such as PVD or CVD.

As with the lower electrode 21, the upper electrode 23 is a stack of the metal layer 23A and the carbon-containing layer 23B, and has a configuration in which the carbon-containing layer 23B and the metal layer 23A are stacked in this order from the side of the switching layer 22.

As with the metal layer 21A, the metal layer 23A includes a wiring line material used in a semiconductor process, for example, a material such as tungsten (W), tungsten nitride (WN), titanium nitride (TiN), copper (Cu), aluminum (Al), molybdenum (Mo), tantalum (Ta), tantalum nitride (TaN), or silicide. In a case where the metal layer 23A includes a material prone to ionic conduction in an electric field, such as Cu, a surface of the metal layer 23A including the material such as Cu may be covered with a material less prone to ionic conduction and thermal diffusion, such as W, WN, titanium nitride (TiN), or TaN.

As with the carbon-containing layer 21B, the carbon-containing layer 23B is provided to be in direct contact with the switching layer 22. The carbon-containing layer 23B includes carbon (C) and, as an additive element, at least one of germanium (Ge), phosphorus (P), or arsenic (As). As illustrated in FIG. 2, the additive element added to the carbon-containing layer 23B is diffused in the vicinity of an interface with the switching layer 22 by application of voltage. Thus, an excellent interface is formed between the carbon-containing layer 23B and the switching layer 22, and generation of leakage current and variation in switching threshold voltage are reduced. Furthermore, the diffusion of the additive element in the vicinity of the interface between the carbon-containing layer 23B and the switching layer 22 enhances adhesion between the carbon-containing layer 23B and the switching layer 22.

An added amount of the additive element is preferably that the total amount of all additive elements included in the carbon-containing layer 23B is, for example, from 3 at % to 20 at %. In a case where the added amount is less than 3 at %, it is difficult to achieve the sufficient reductions of leakage current and variation in switching threshold voltage and the enhancement of the adhesion. In a case where the added amount is more than 20 at %, it becomes difficult to obtain excellent selection characteristics, for example, for reasons of a too strong monotectoid reaction in the carbon-containing layer 23B, etc. Furthermore, there is a possibility that delamination is likely to occur.

The thickness of the carbon-containing layer 23B is preferably, for example, from 3 nm to 20 nm. In a case where the thickness is less than 3 nm, there is a possibility that it may fail to make enough improvements in generation of leakage current and variation in switching threshold voltage.

The upper electrode 23 is able to be formed together with the metal layer 23A and the carbon-containing layer 23B by means of a well-known film-formation technique, for example, such as PVD or CVD.

The switching device 20 of the present embodiment has switching characteristics that while in an initial state, the switching device 20 has a high resistance value (is in a high-resistance state (off state)), and, when applied with voltage, has a low resistance value (goes into a low-resistance state (on state)) at a certain voltage (the switching threshold voltage). Furthermore, the switching device 20 is not kept in on state because it goes back into the high-resistance state when the applied voltage is decreased to below the switching threshold voltage or when the application of voltage is stopped. That is, the switching device 20 has no memory operations performed upon phase change (between a non-crystalline phase (an amorphous phase) and a crystalline phase) of the switching layer 22 caused by application of a voltage pulse or a current pulse from the not-illustrated power supply circuit (the pulse applying means) through the lower electrode 21 and the upper electrode 23.

Besides the above-described configuration of the switching device 20, the switching device 20 of the present embodiment may have the following configurations.

For example, the switching device 20 may be provided with a high-resistance layer having a higher insulation property than the switching layer 22 and including, for example, an oxide or nitride of a metallic element or a nonmetallic element or a mixture of these between the lower electrode 21 and the switching layer 22 or between the switching layer 22 and the upper electrode 23. It is to be noted that, for example, in a case where the high-resistance layer is provided between the lower electrode 21 and the switching layer 22, this high-resistance layer is able to play a role of the carbon-containing layer 21B included in the lower electrode 21. The same applies to a case where the high-resistance layer is provided between the switching layer 22 and the upper electrode 23. Furthermore, the switching layer 22 may have, for example, a multi-layer structure, i.e., may include multiple layers stacked.

### 1-2. Configuration of Memory Cell Array

FIG. 3 is a perspective view of an example of a configuration of the memory cell array 1. The memory cell array 1 corresponds to a specific example of a “storage unit” of the present disclosure. The memory cell array 1 has a so-called cross-point array structure, and, for example, as illustrated in FIG. 3, includes memory cells 10, one at each position (cross-point) where a word line WL and a bit line BL are opposed to each other. That is, the memory cell array 1 includes a plurality of word lines WL, a plurality of bit lines BL, and a plurality of memory cells 10 disposed one at each cross-point. In this way, the memory cell array 1 of the present embodiment may have a configuration in which the plurality of memory cells 10 is disposed in a plane (in two dimensions, in an XY plane direction).

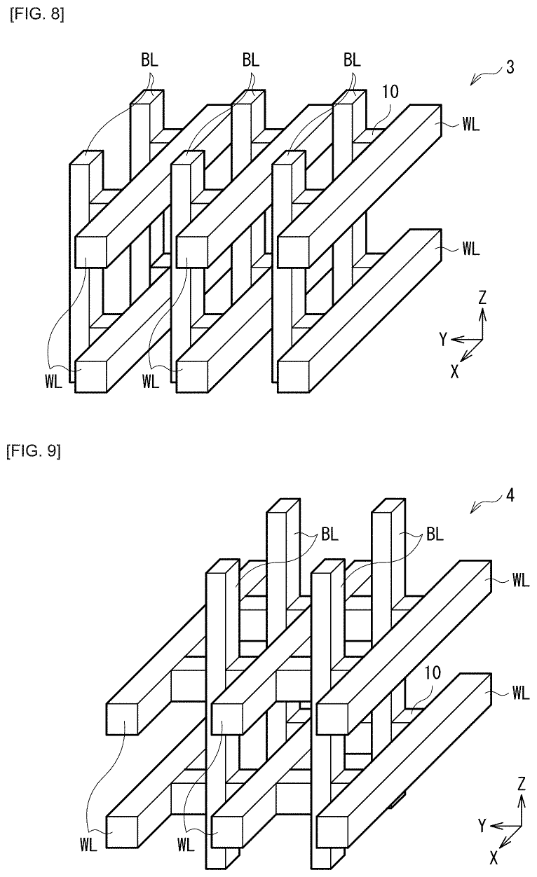

The word lines WL all extend in the same direction. The bit lines BL extend in the same direction that is a direction different from the extending direction of the word lines WL (for example, a direction orthogonal to the extending direction of the word lines WL). It is to be noted that the plurality of word lines WL is disposed in one or more layers, and may be disposed to be divided into multiple layers, for example, as illustrated in FIG. 8. The plurality of bit lines BL is disposed in one or more layers, and may be disposed to be divided into multiple layers, for example, as illustrated in FIG. 8.

The memory cell array 1 includes the plurality of memory cells 10 two-dimensionally disposed on a substrate. The substrate includes, for example, a wiring line group electrically coupled to the word lines WL and the bit lines BL, a circuit for connecting the wiring line group to an external circuit, etc. The memory cell 10 includes the memory device 30 and the switching device 20 directly coupled to the memory device 30. Specifically, the memory cell 10 has a configuration in which the memory layer 31 included in the memory device 30 and the switching layer 22 included in the switching device 20 are stacked through an intermediate electrode 41. The switching device 20 corresponds to a specific example of a “switching device” of the present disclosure. The memory device 30 corresponds to a specific example of a “memory device” of the present disclosure.

The memory device 30 is disposed, for example, nearer the bit line BL, and the switching device 20 is disposed, for example, nearer the word line WL. It is to be noted that the memory device 30 may be disposed nearer the word line WL, and the switching device 20 may be disposed nearer the bit line BL. Furthermore, in a case where in some layer, the memory devices 30 are disposed nearer the bit lines BL, and the switching devices 20 are disposed nearer the word lines WL, in a layer adjacent to that layer, the memory devices 30 may be disposed nearer the word lines WL, and the switching devices 20 may be disposed nearer the bit lines BL. Moreover, in each layer, the memory devices 30 may be formed on top of the switching devices 20, or, conversely, the switching devices 20 may be formed on top of the memory devices 30.

### (Memory Device)

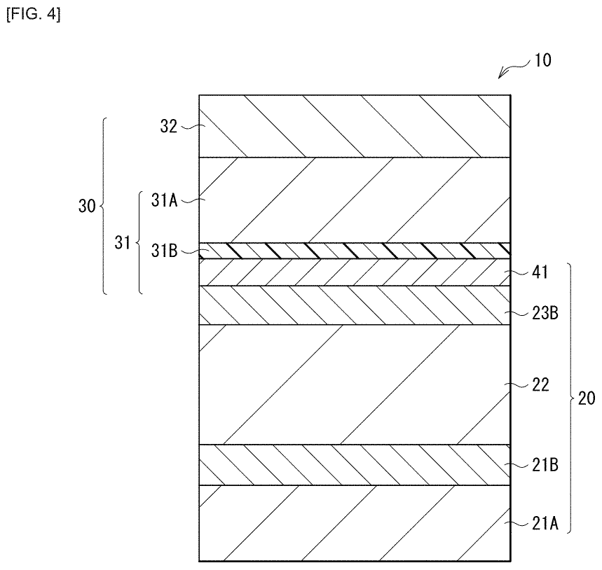

FIG. 4 illustrates an example of a cross-sectional configuration of the memory cell 10 in the memory cell array 1. The memory device 30 includes a lower electrode, an upper electrode 32 disposed to be opposed to the lower electrode, and the memory layer 31 provided between the lower electrode and the upper electrode 32. The memory layer 31 has, for example, a stack structure in which a resistance change layer 31B and an ion source layer 31A are stacked from the side of the lower electrode. It is to be noted that in the present embodiment, the intermediate electrode 41 provided between the memory layer 31 included in the memory device 30 and the switching layer 22 included in the switching device 20 also serves as the above-described lower electrode of the memory device 30.

The upper electrode 32 includes a wiring line material used in a semiconductor process, for example, a material such as tungsten (W), tungsten nitride (WN), titanium nitride (TiN), copper (Cu), aluminum (Al), molybdenum (Mo), tantalum (Ta), tantalum nitride (TaN), or silicide. In a case where the lower electrode 21 includes a material prone to ionic conduction in an electric field, such as Cu, a surface of the lower electrode 21 including the material such as Cu may be covered with a material less prone to ionic conduction and thermal diffusion, such as W, WN, titanium nitride (TiN), or TaN.

The ion source layer 31A includes a mobile element that forms a conduction path in the resistance change layer 31B upon application of an electrical field. This mobile element is, for example, a transition metal element, aluminum (Al), copper (Cu), or a chalcogen element. Examples of the chalcogen element include tellurium (Te), selenium (Se), and sulfur (S). The transition metal element is an element in Groups 4 to 6 of the Periodic Table, for example, such as titanium (Ti), zirconium (Zr), hafnium (Hf), vanadium (V), niobium (Nb), tantalum (Ta), chromium (Cr), molybdenum (Mo), or tungsten (W). The ion source layer 31A includes one, or two or more of the above-described mobile elements. Furthermore, the ion source layer 31A may include an element such as oxygen (O), nitrogen (N), an element other than the above-described mobile elements (for example, manganese (Mn), cobalt (Co), iron (Fe), nickel (Ni), or platinum (Pt)), or silicon (Si). The thickness of the ion source layer 31A is preferably, for example, from 15 nm to 40 nm.

The resistance change layer 31B includes, for example, an oxide of a metallic element or a nonmetallic element or a nitride of a metallic element or a nonmetallic element; a resistance value of the resistance change layer 31B changes in a case where a predetermined voltage is applied to between the intermediate electrode 41 and the upper electrode 32. For example, when the voltage is applied to between the intermediate electrode 41 and the upper electrode 32, the transition metal element included in the ion source layer 31A moves into the resistance change layer 31B, and a conduction path is formed, which makes the resistance change layer 31B low in resistance. Furthermore, a structural defect, such as an oxygen defect or a nitrogen defect, is developed in the resistance change layer 31B, and a conduction path is formed, and thus the resistance change layer 31B becomes low in resistance. Moreover, the application of voltage in a direction opposite to the direction of voltage applied when the resistance change layer 31B becomes low in resistance causes the conduction path to be cut off, or changes the conductive property, which makes the resistance change layer high in resistance.

It is to be noted that the whole of the metallic element and the nonmetallic element included in the resistance change layer 31B does not necessarily have to be in a state of an oxide, and they may be in a state of being partially oxidized. Furthermore, an initial resistance value of the resistance change layer 31B only has to allow a device resistance of, for example, about a few MΩ to about a few hundred GΩ to be achieved, and its optimum value changes depending on the size of the device and a resistance value of the ion source layer. The thickness of the resistance change layer 31B is preferably, for example, from 0.5 nm to 2 nm.

The intermediate electrode 41 may also serve as an upper electrode of the switching device 20, or may be provided separately from the upper electrode of the switching device 20. In a case where the intermediate electrode 41 also serves as the upper electrode of the switching device 20, as with the above-described upper electrode 23, it is preferable to form an electrode layer having a similar configuration to the above-described carbon-containing layer 23B on the side of the switching device 20.

On the side of the memory layer 31, for example, it is preferable to form an electrode layer including a material that prevents the chalcogen elements included in the switching layer 22 and the ion source layer 31A from being diffused by application of an electrical field. One reason for this is that, for example, although the ion source layer 31A includes the transition metal element as an element that causes it to perform memory operation and be kept in a write state, if the transition metal element is diffused into the switching layer 22 by application of an electrical field, there is a possibility that the switching characteristics may degrade. Therefore, it is preferable that the intermediate electrode 41 include a barrier material having a barrier property that prevents diffusion of the transition metal element and ionic conduction on the side of the memory layer 31. Examples of the barrier material include tungsten (W), tungsten nitride (WN), titanium nitride (TiN), carbon (C), molybdenum (Mo), tantalum (Ta), tantalum nitride (TaN), titanium tungsten (TiW), silicide, etc.

### (Switching Device)

In the switching device 20 of the memory cell array 1, as described above, the intermediate electrode 41 provided between the memory layer 31 included in the memory device 30 and the switching layer 22 included in the switching device 20 also serves as the upper electrode 23. Furthermore, the lower electrode 21 may also serve as the bit line BL, or may be provided separately from the bit line BL. In a case where the lower electrode 21 is provided separately from the bit line BL, the lower electrode 21 is electrically coupled to the bit line BL. It is to be noted that in a case where the switching device 20 is provided nearer the word line WL, the lower electrode 21 may also serve as the word line WL, or may be provided separately from the word line WL. Here, in a case where the lower electrode 21 is provided separately from the word line WL, the lower electrode 21 is electrically coupled to the word line WL.

Furthermore, the memory cell 10 may have the following configurations, besides the configuration illustrated in FIG. 4.

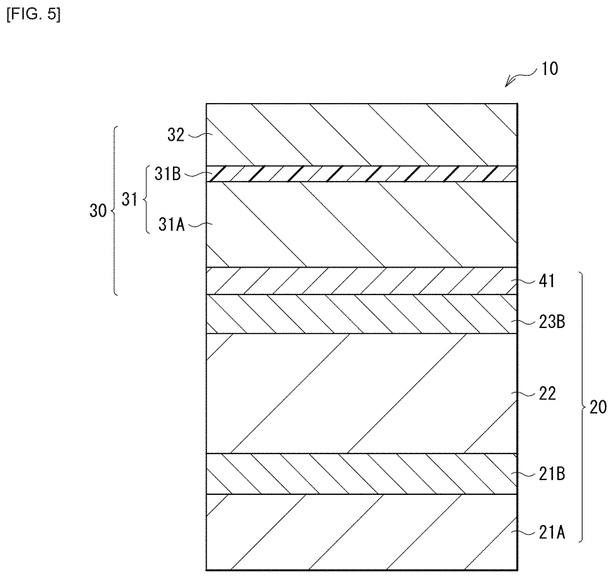

In the memory cell 10 illustrated in FIG. 5, the memory device 30 has a configuration in which the resistance change layer 31B is provided between the ion source layer 31A and the upper electrode 32. The memory cell 10 illustrated in FIG. 6 has a configuration in which the intermediate electrode 41 is omitted, and the switching layer 22 and the memory layer 31 are stacked with the resistance change layer 31B between them. It is to be noted that in a case where the resistance change layer 31B is disposed on the side in contact with the switching device 20 as illustrated in FIG. 6, the carbon-containing layer 23B between the resistance change layer 31B and the switching layer 22 may be omitted. Furthermore, in the memory cells 10 illustrated in FIGS. 4 to 6, the respective switching devices 20 have the configuration of the switching device 20 illustrated in FIG. 1 as an example; however, they are not limited to this. Moreover, the memory cell 10 may have a configuration in which a plurality of the switching devices 20 and a plurality of the memory devices 30 are, for example, alternately stacked.

Furthermore, in the memory cell array 1 of the present embodiment, the memory device 30 may adopt any form of memory, for example, such as an OTP (One Time Programable) memory that allows for only one-time writing using a fuse or an anti-fuse, a PCRAM that is a unipolar phase-change memory, or a magnetic memory using, for example, a magneto-resistance change device.

### 1-3. Workings and Effects

In recent years, a larger capacity has been demanded of a non-volatile memory, and various resistive memories have been discussed. However, in a 1T1R configuration in which one memory device is disposed for one access transistor, the area per unit cell is larger, and thus it has a limitation in achieving the larger capacity. Accordingly, a cross-point memory having a three-dimensional structure has been considered.

In the cross-point memory, as described above, memory cells each including a memory device and a switching device that are coupled in series are disposed at points of intersection (cross-points) between intersecting wiring lines, and thus the floor area per unit cell is made smaller. For example, it is possible to achieve an area per unit cell of 2F², where F denotes a reference line width. Therefore, it is possible to make the cell area smaller, and by stacking a plurality of cross-point arrays in layers, it becomes possible to achieve a larger-capacity memory. Examples of the switching device include a PN diode, an avalanche diode, and a switching device including metallic oxide. Besides these, a switching device including, for example, a chalcogenide material (an ovonic threshold switch (OTS) device) may be used.

To suppress leakage current in the cross-point array, the switching device used in the cross-point memory is demanded to be low in leakage current when it is off and have less variation in switching threshold voltage. To address this, for example, there is disclosed a method of using carbon in an electrode material in contact with a chalcogenide layer included in a switching device, and it is reported that for example, in a case where the chalcogenide layer includes selenium (Se), variation in threshold voltage is improved by using a carbon material in an electrode. However, the above-described switching device is disadvantageous in that it is difficult to maintain the characteristics at a process temperature (for example, 400° C.).

A heat-resisting property is able to be enhanced, for example, by adding an element such as germanium (Ge) or arsenic (As) to the chalcogenide layer, thereby changing the composition ratio; however, it leads to an issue that variation in switching threshold voltage becomes larger. Furthermore, for example, in a case where tellurium (Te) is used in the chalcogenide layer, and Ge is added to that chalcogenide layer, variation in switching threshold voltage is improved; however, if an added amount of Ge is too much, there is an issue that the switching threshold voltage decreases, and the leakage current increases. In this way, despite using the carbon material in the electrode, it is still difficult to reduce variation in switching threshold voltage while reducing generation of leakage current.

In contrast, in the present embodiment, as the lower electrode 21 and the upper electrode 23 that hold the switching layer 22 including at least one chalcogen element selected from sulfur (S), selenium (Se), and tellurium (Te) between them, the carbon-containing layers 21B and 23B including carbon (C) and, as an additive element, at least one of germanium (Ge), phosphorus (P), or arsenic (As) are provided. Thus, the above-described additive element is diffused in the vicinity of the interface with the switching layer 22, and it becomes possible to form an excellent contact interface with the switching layer 22.

From the above, in the switching device 20 of the present embodiment, as the lower electrode 21 and the upper electrode 23 that hold the switching layer 22 between them, the carbon-containing layers 21B and 23B including carbon (C) and, as an additive element, at least one of germanium (Ge), phosphorus (P), or arsenic (As) are formed. Thus, the additive element is diffused in the vicinity of the interface with the switching layer 22, and an excellent contact interface is formed between the carbon-containing layers 21B and 23B and the switching layer 22. Therefore, it is possible to reduce generation of leakage current and variation in switching threshold voltage. Accordingly, it becomes possible to reduce the occurrence of an operating error of a large-scale cross-point memory cell array, and thus becomes possible to provide a larger-capacity cross-point memory.

Furthermore, as described above, the switching device used in the cross-point memory is demanded to maintain its characteristics after a thermal history at about 400° C. in a semiconductor process. In addition, the switching device used in the cross-point memory is also demanded a high cyclic characteristic. In the switching device in which a carbon material is merely used in the electrode in contact with the chalcogenide layer of the above-described device, it is difficult to satisfy both of electrical characteristics, such as leakage current and variation in switching threshold voltage, and the heat-resisting property. In contrast, in the switching device 20 of the present embodiment, it is possible to maintain the electrical characteristics even in a semiconductor process in which a thermal history at about 400° C. is applied.

Subsequently, modification examples of the above-described embodiment are described. In the following, a similar component to that of the above-described embodiment is assigned the same reference numeral, and its description is omitted accordingly.

### 2. Modification Examples

### 2-1. Modification Example 1

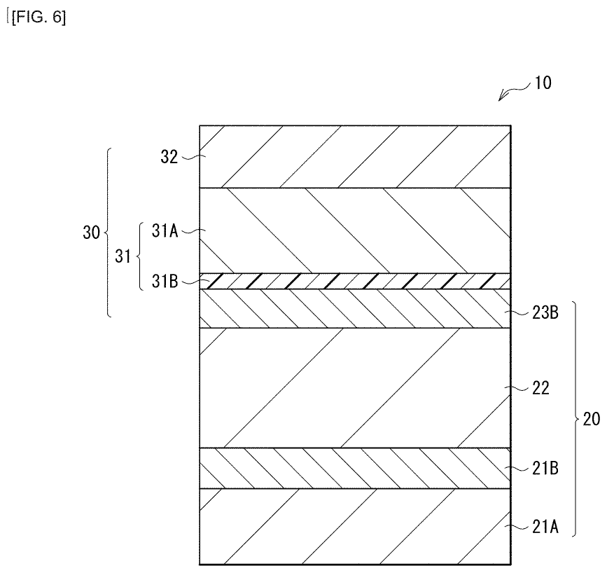

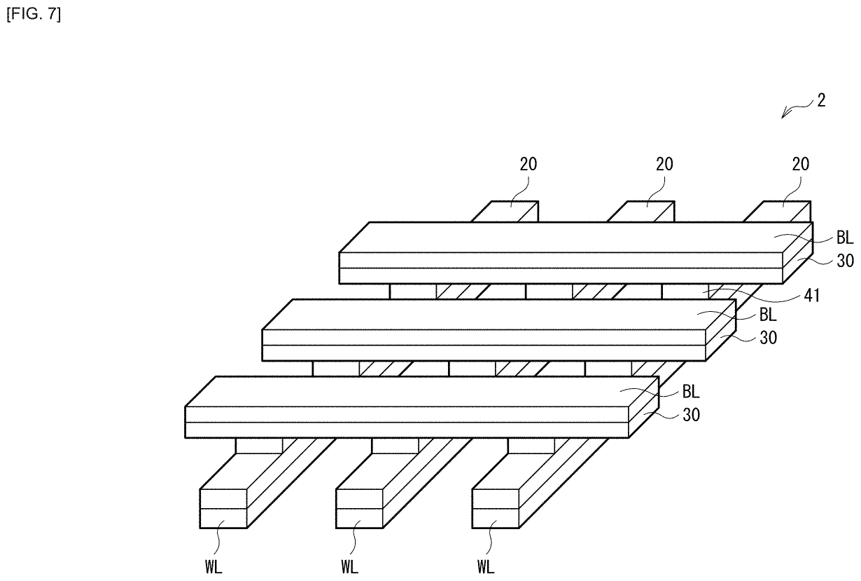

FIG. 7 is a perspective view of an example of a configuration of a memory cell array 2 according to a modification example of the present disclosure. This memory cell array 2 has a so-called cross-point array structure as with the above-described memory cell array 1. In the present modification example, the respective memory layers 31 of the memory devices 30 extend along the bit lines BL extending in the same direction. The respective switching layers 22 of the switching devices 20 extend along the word lines WL extending in a direction different from the extending direction of the bit lines BL (for example, a direction orthogonal to the extending direction of the bit lines BL). At each of cross-points between the plurality of word lines WL and the plurality of bit lines BL, the switching layer 22 and the memory layer 31 are stacked through the intermediate electrode 41.

In this way, the switching devices 20 and the memory devices 30 are configured not to be provided only at the cross-points but to extend in the extending direction of the word lines WL and the extending direction of the bit lines BL, respectively; therefore, it is possible to form a film of a switching device layer or a memory device layer simultaneously with a layer to be made into the bit line BL or the word line WL and perform shaping by a photolithography process collectively. Thus, it is possible to reduce the number of process steps.

### 2-2. Modification Example 2

FIGS. 8 to 11 are perspective views of examples of respective configurations of memory cell arrays 3 to 6 having a three-dimensional structure according to modification examples of the present disclosure. In these memory cell arrays having a three-dimensional structure, the word lines WL extend in the same direction. The bit lines BL extend in the same direction that is a direction different from the extending direction of the word lines WL (for example, a direction orthogonal to the extending direction of the word lines WL). Furthermore, the plurality of word lines WL and the plurality of bit lines BL are each disposed in multiple layers.

In a case where the plurality of word lines WL is disposed to be divided into multiple layers, the plurality of bit lines BL is disposed in a layer between a first layer in which multiple word lines WL are disposed and a second layer that is adjacent to the first layer and multiple word lines WL are disposed therein. In a case where the plurality of bit lines BL is disposed to be divided into multiple layers, the plurality of word lines WL is disposed in a layer between a third layer in which multiple bit lines BL are disposed and a fourth layer that is adjacent to the third layer and multiple bit lines BL are disposed therein. In a case where the plurality of word lines WL is disposed to be divided into multiple layers, and the plurality of bit lines BL is disposed to be divided into multiple layers, the plurality of word lines WL and the plurality of bit lines BL are alternately disposed in a stacking direction of the memory cell array.

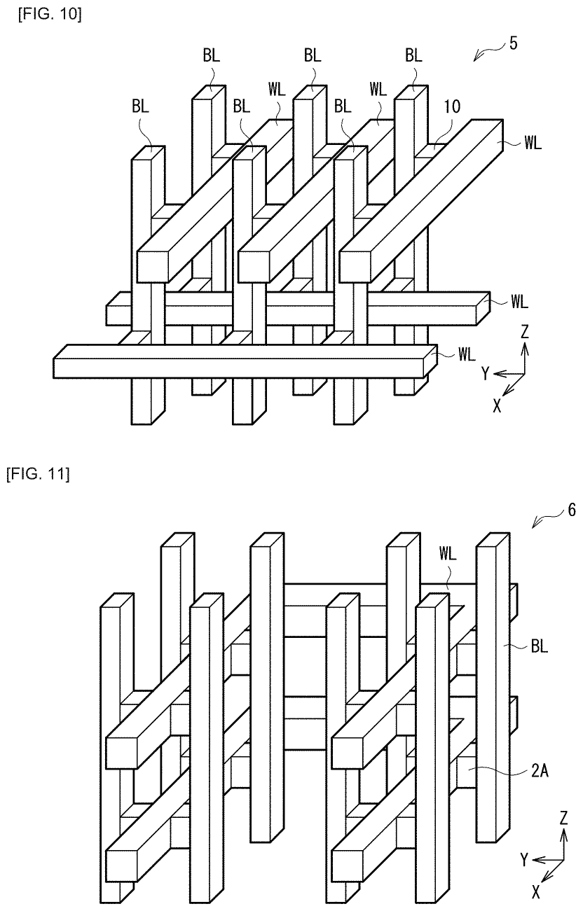

The memory cell arrays in the present modification examples have a vertical cross-point structure in which either the word lines WL or the bit lines BL are provided parallel to a Z-axis direction, and the other ones are provided parallel to an XY plane direction. For example, a configuration may be employed in which, as illustrated in FIG. 8, the plurality of word lines WL extends in an X-axis direction, the plurality of bit lines BL extends in the Z-axis direction, and the memory cells 10 are disposed at their cross-points. Furthermore, a configuration may be employed in which, as illustrated in FIG. 9, the memory cells 10 are disposed on the both sides of the cross-points between the plurality of word lines WL extending in the X-axis direction and the plurality of bit lines BL extending in the Z-axis direction. Moreover, a configuration may be employed that includes, as illustrated in FIG. 10, the plurality of bit lines BL extending in the Z-axis direction and two types of pluralities of word lines WL extending in two directions, the X-axis direction and a Y-axis direction. Furthermore, the plurality of word lines WL and the plurality of bit lines BL do not necessarily have to extend in one direction. For example, a configuration may be employed in which, as illustrated in FIG. 11, for example, the plurality of bit lines BL extends in the Z-axis direction, and the plurality of word lines WL extends in the XY plane in a so-called U-shape, i.e., extends in the X-axis direction, and is bent in the Y-axis direction, and then is further bent in the X-axis direction.

As described above, the memory cell array of the present disclosure has the three-dimensional structure in which the plurality of memory cells 10 is disposed in a plane (in two directions, in the XY plane direction) and is stacked in the Z-axis direction. Therefore, it is possible to provide a higher-density, larger-capacity storage unit.

### 3. Application Example

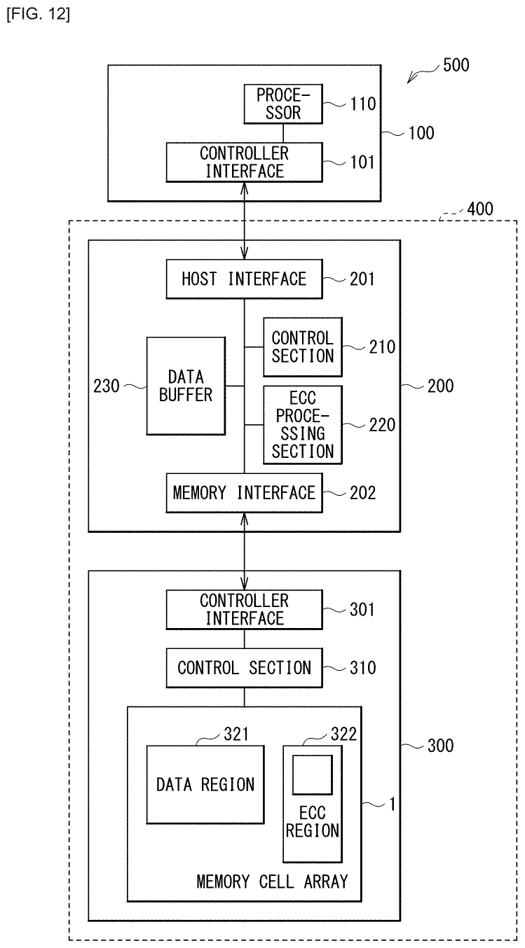

FIG. 12 illustrates a configuration of a data storage system (a data storage system 500) that includes a non-volatile memory system (a memory system 400) having the memory cell array 1 (or the memory cell arrays 2 to 5) including the memory cells 10 described in the above-described embodiment. This data storage system 500 includes a host computer 100, a memory controller 200, and a memory 300. The memory system 400 includes the memory controller 200 and the memory 300.

The host computer 100 issues a command to order a process of reading data from the memory 300, a process of writing data in the memory 300, a process related to error correction, etc. This host computer 100 includes a processor 110 that performs processing as the host computer 100 and a controller interface 101 for communicating with the memory controller 200.

The memory controller 200 performs request control on the memory 300 in accordance with a command from the host computer 100. This memory controller 200 includes a control section 210, an ECC processing section 220, a data buffer 230, a host interface 201, and a memory interface 202.

The control section 210 controls the entire memory controller 200. This control section 210 interprets a command given from the host computer 100, and issues a necessary request to the memory 300.

The ECC processing section 220 performs generation of an error correcting code (ECC: Error Correcting Code) of data recorded in the memory 300 and an error detection and correction process on data read from the memory 300.

The data buffer 230 is a buffer for temporarily retaining data, such as write data received from the host computer 100 or read data received from the memory 300, when the data is transferred.

The host interface 201 is an interface for communicating with the host computer 100. The memory interface 202 is an interface for communicating with the memory 300.

The memory 300 includes a control section 310, a memory cell array 320, and a controller interface 301. The control section 310 controls the entire memory 300, and controls access to the memory cell array 320 in accordance with a request received from the memory controller 200. The controller interface 301 is an interface for communicating with the memory controller 200.

As the memory cell array 320, the memory cell array 1 (or 2 to 5) having a cross-point array structure is used; the memory cell array 1 includes the plurality of memory cells 10 disposed one at each cross-point located at each of points of intersection between the plurality of word lines WL and the plurality of bit lines BL. The memory cells 10 include the switching device 20 (switching devices 20, 20B, 20C, or 20D) described in the above-described embodiment and the memory device. This memory device is, as described above, a resistive random access memory (the memory device 30) having a stack structure of the resistance change layer and the ion source layer; the ion source layer includes a mobile element that forms a conduction path in that resistance change layer by means of application of an electrical field. Besides this, for example, a non-volatile memory (NVM: Non-Volatile Memory) such as a ReRAM (Resistance Random Access Memory) using metallic oxide, an OTP (One Time Programable) memory that allows for only one-time writing using a fuse or an anti-fuse, a PCRAM that is a unipolar phase-change memory, or a magnetic memory using a magneto-resistance change device, may be used.

The memory cells 10 included in the memory cell array 320 include a data region 321 and an ECC region 322. The data region 321 is a region for storing normal data.

In this way, by using the cross-point memory cell array 1 (or the memory cell arrays 2 to 5) including the switching device 20 according to the present disclosure in the memory system, it becomes possible to enhance the performance, such as the operating speed

### 4. Examples

In the following, specific examples of the present disclosure are described.

### Experiment 1

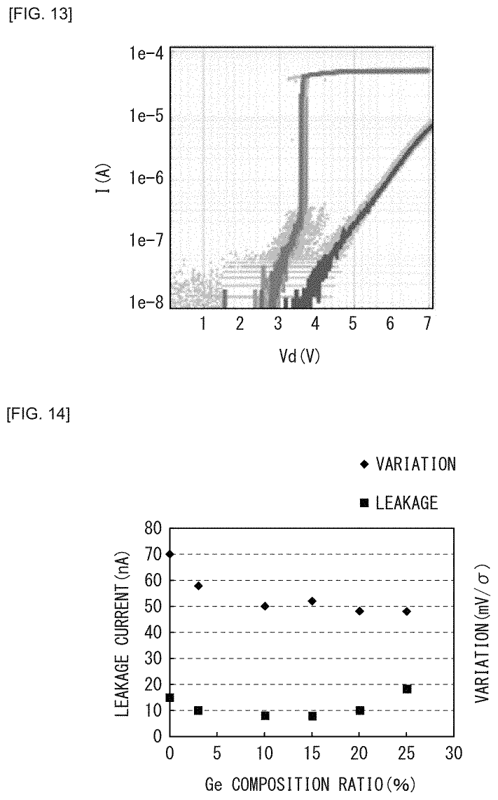

First, a surface of a 160-nm φ plug including TiN was cleaned by reverse sputtering. Next, as a metal layer, a W film for a wiring line was formed on the plug, and after that, as a carbon-containing layer, a C target and a Ge target were simultaneously discharged by co-sputtering, and thereby a C—Ge film was formed, and a lower electrode was formed. At this time, film-formation power was adjusted to cause the composition ratio of C to Ge to be 90:10 and its thickness to be 10 nm. Next, a film of a switching layer including BCGaTw was formed with a film thickness of 30 nm on the lower electrode by reactive sputtering while pouring nitrogen into a film-formation chamber. Then, the C90-Ge10 film as the carbon-containing layer was formed with a thickness of 10 nm, and after that, the W film for a wiring line was formed, and an upper electrode was formed. Next, after the device was processed by patterning, the processed device was coupled to a MOS transistor of a substrate, and a 1 transistor-1 switching device was manufactured (Experimental Example 1). After a pad electrode including Al was formed on this 1 transistor-1 switching device, it was heat-treated at 400° C. for two hours, and its characteristics were evaluated. FIG. 13 is a current-voltage curve illustrating the characteristic evaluation.

In the switching device in Experimental Example 1, a switching voltage was 3.7 V; variation in switching threshold voltage was 46 mV/σ; and an off leakage current was 8 nA.

Furthermore, a stacked film (a W film/a C-Ge film/a switching layer/a C-Ge film/a W film) having the configuration in Experimental Example 1 was formed, and adhesion and temperature endurance of the switching layer were examined. First, a W film/a C-Ge film/a switching layer/a C-Ge film/a W film were formed by means of a similar method to that is described above. After this was heat-treated at various temperatures (320° C., 375° C., 400° C., and 425° C.), a tape peeling test was conducted. As a result, delamination was not found at any temperatures.

### Experiment 2

Subsequently, five types of switching devices were manufactured using a similar method to Experimental Example 1, except for using a C-Ge film as a carbon-containing layer and different added amounts of Ge (Experimental Examples 2 to 6). Furthermore, two types of switching devices were manufactured using the similar method to Experimental Example 1, except for using a C film as a carbon-containing layer and a BCGaGeTe film as a switching layer, and different added amounts of Ge to a switching layer (Experimental Examples 7 and 8). Moreover, two types of switching devices were manufactured using the similar method to Experimental Example 1, except for using a C—P film or a C—As film as a carbon-containing layer (Experimental Examples 9 and 10). In Experimental Examples 2 to 10, current-voltage (IV) characteristics and tape peeling tests were conducted in a similar manner to Experimental Example 1. Table 1 tabulates respective compositions of a carbon-containing layer and a switching layer, switching voltage, variation in switching threshold voltage (in Table 1, written as “variation”), leakage current, and heat resisting temperature obtained in the tape peeling test in Experimental Examples 1 to 10. FIG. 14 illustrates a relationship among an added amount of Ge to the carbon-containing layer, leakage current, and variation in switching threshold voltage based on Experimental Examples 1 to 7.

TABLE 1

| | | | | | | TAPE |
|---|---|---|---|---|---|---|
| | | | | | | PEELING |
| | | | | | | TEST HEAT |
| | CARBON- | | SWITCHING | | LEAKAGE | RESISTING |
| | CONTAINING | SWITCHING | VOLTAGE | VARIATION | CURRENT | TEMPERATURE |
| | LAYER | LAYER | (V) | (mV/σ) | (nA) | (° C.) |
| Experimental | C90-Ge10 | BCGaTe | 4.0 | 50 | 8 | 425° C. |
| Example 1 | | | | | | |
| Experimental | C | BCGaTe | 4.0 | 70 | 15 | 400° C. |
| Example 2 | | | | | | |
| Experimental | C97-Ge3 | BCGaTe | 4.0 | 58 | 10 | 400° C. |
| Example 3 | | | | | | |
| Experimental | C85-Ge15 | BCGaTe | 3.8 | 52 | 8 | 425° C. |
| Example 4 | | | | | | |
| Experimental | C80-Ge20 | BCGaTe | 3.8 | 48 | 10 | 400° C. |
| Example 5 | | | | | | |
| Experimental | C75-Ge25 | BCGaTe | 3.5 | 48 | 18 | 375° C. |
| Example 6 | | | | | | |
| Experimental | C | BCGaTe- | 3.8 | 48 | 20 | 375° C. |
| Example 7 | | Ge 1at % | | | | |
| Experimental | C | BCGaTe- | 3.5 | 45 | 25 | 375° C. |
| Example 8 | | Ge 3at % | | | | |
| Experimental | C90-P10 | BCGaTe | 3.8 | 53 | 12 | 400° C. |
| Example 9 | | | | | | |
| Experimental | C90-As10 | BCGaTe | 3.9 | 52 | 10 | 400° C. |
| Example 10 | | | | | | |

From Table 2, regarding the presence or absence of the addition of Ge to the carbon-containing layer, when compared Experimental Example 1 in which Ge was added at 10 at % and Experimental Example 2 in which the carbon-containing layer included only a carbon material, it was confirmed that by adding Ge to the carbon-containing layer, the variation in switching threshold voltage was reduced by 20 mV/σ from 70 mV/σ to 50 mV/σ. The leakage current was decreased from 15 nA to 8 nA. The heat resisting temperature in the tape peeling test was increased from 400° C. to 425° C.

In a cross-point memory, by improving variation in switching threshold voltage of a switching device, a switching operation window during a memory operation is widened, and it becomes possible to reduce the occurrence of an operating error. The leakage current of the switching device is important in how large a scale of memory array is able to be activated. The delamination endurance is important in performing a manufacturing process of a cross-point memory cell array. From Table 2, it was found that these characteristics are improved by adding Ge to the carbon-containing layer.

Next, regarding the optimum added amount of Ge, judging from FIG. 14 in which respective leakage currents and variations in switching threshold voltage in Experimental Examples 1 to 7 are put together, it was found that the larger the added amount of Ge was within a range up to 25 at %, the more the variation in switching threshold voltage was able to be reduced. Meanwhile, regarding the leakage current, it was found that it decreased when the added amount of Ge was 3 at %, and had a lower limit when the added amount of Ge was in a range between 3 at % and 20 at %. Furthermore, when the added amount of Ge was 25 at %, the leakage current again increased. Although this result is not necessarily clear, this is presumably due to the diffusion of Ge from the carbon-containing layer added with Ge into an interface with the switching layer, which caused an excellent bonding to each electrode to be obtained. This effect of Ge makes it infer that in a case where the added amount is within a range from 3 at % to 20 at %, the amount of Ge diffused is appropriate, and therefore, both effects of reduction of leakage current and reduction of variation in switching threshold voltage are obtained; however, if the added amount is increased to 25 at %, the amount of Ge diffused into the switching layer becomes too much, and it goes into the same state in a case where Ge is added to the switching layer, and thus the effect of reducing the leakage current is lessened.

Next, a case where Ge is added to the switching layer is described with the result of Experimental Examples 1, 7, and 8. In Experimental Examples 7 and 8 in which Ge was added to the switching layer at 1 at % and 3 at %, respectively, the variation in switching threshold voltage was improved as the added amount of Ge became larger; however, the switching voltage decreased with increasing leakage current. From this, in a case where Ge is added to the switching layer, it is necessary to take measures, such as increasing the thickness of the switching layer, to reduce the leakage current to a favorable value. From these results, it was found that by adding Ge to the carbon-containing layer, it becomes possible to obtain the effect of reducing the variation in switching threshold voltage as with a case where Ge is added to the switching layer without increasing the thickness of the switching layer and also possible to reduce the leakage current.

It is to be noted that from Experimental Examples 9 and 10, it was found that P or As may be used as an element added to the carbon-containing layer. As an additive element, P was used in Experimental Example 9, and As was used in Experimental Example 10; however, these additive elements each promote the stabilization of an amorphous structure of the switching layer. From Table 2, it was found that as with Ge, P and As have effects of improving the variation in switching threshold voltage and reducing the generation of leakage current.

As above, from the results of Experiment 2, it was found that by adding the additive element, such as Ge, P, or As, to the carbon-containing layer in contact with the switching layer within a range from 3 at % to 20 at %, it becomes possible to reduce the generation of leakage current and the variation in switching threshold voltage. It is to be noted that in above-described Experimental Examples 1 to 10, the composition of the switching layer was BCGaTe; however, it is not limited to this, and switching layers having other compositions, for example, including SiGeAsTe, BCTe, GeAsSe, GeSiAsSe, and BCAsSe, achieve similar effects.

The present disclosure has been described above with the embodiment and modification examples; however, contents of the present disclosure are not limited to the above-described embodiment, etc., and various modifications are possible. For example, as a method of operation of the memory cell array (for example, the memory cell array 1) using the memory device 30 of the present disclosure, various biasing methods, such as the well-known V, V/2 method and a V, V/3 method, may be used.

Furthermore, for example, the present disclosure may have the following configurations.

(1)

A switching device including:

a first electrode;

a second electrode disposed to be opposed to the first electrode; and

a switching layer provided between the first electrode and the second electrode, the switching layer including at least one chalcogen element selected from sulfur (S), selenium (Se), and tellurium (Te),

in which at least one of the first electrode or the second electrode includes carbon (C) and, as an additive element, at least one of germanium (Ge), phosphorus (P), or arsenic (As).

(2)

The switching device according to (1), in which an added amount of the additive element is from 3 at % to 20 at %.

(3)

The switching device according to (1) or (2), in which the switching layer further includes at least one of boron (B) or gallium (Ga).

(4)

The switching device according to any one of (1) to (3), in which at least one of the first electrode or the second electrode has a stack structure of a carbon-containing layer and a metal layer, the carbon-containing layer including carbon (C) and, as the additive element, at least one of germanium (Ge), phosphorus (P), or arsenic (As).

(5)

The switching device according to (4), in which the carbon-containing layer is provided in contact with the switching layer.

(6)

The switching device according to (4) or (5), in which the carbon-containing layer has a film thickness from 3 nm to 20 nm.

(7)

The switching device according to any one of (1) to (6), in which without involving a phase change between a non-crystalline phase and a crystalline phase, the switching layer is changed into a low-resistance state by increasing an applied voltage to a predetermined threshold voltage or higher, and is changed into a high-resistance state by decreasing the applied voltage to a voltage lower than the threshold voltage.

(8)

A storage unit including

a plurality of memory cells,

the plurality of memory cells each including a memory device and a switching device directly coupled to the memory device,

the switching device including:
a first electrode;
a second electrode disposed to be opposed to the first electrode; and
a switching layer provided between the first electrode and the second electrode, the switching layer including at least one chalcogen element selected from selenium (Se) and sulfur (S),

in which at least one of the first electrode or the second electrode includes carbon (C) and, as an additive element, at least one of germanium (Ge), phosphorus (P), or arsenic (As).

(9)

The storage unit according to (8), in which the memory device is any one of a phase-change memory device, a resistive memory device, and a magneto-resistive memory device.

(10)

The storage unit according to (8) or (9), in which the plurality of memory cells includes two or more memory cells that are stacked.

(11)

A memory system including:

a host computer including a processor;

a memory including a memory cell array that includes a plurality of memory cells; and

a memory controller that performs request control on the memory in accordance with a command from the host computer,
the plurality of memory cells each including a memory device and a switching device directly coupled to the memory device,
the switching device including
   a first electrode,
   a second electrode disposed to be opposed to the first electrode, and
   a switching layer provided between the first electrode and the second electrode, the switching layer including at least one chalcogen element selected from sulfur (S), selenium (Se), and tellurium (Te),

in which at least one of the first electrode or the second electrode includes carbon (C) and, as an additive element, at least one of germanium (Ge), phosphorus (P), or arsenic (As).

This application claims the benefit of Japanese Priority Patent Application JP2018-074639 filed with the Japan Patent Office on Apr. 9, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A switching device comprising:
a first electrode;
a second electrode disposed to be opposed to the first electrode; and
a switching layer provided between the first electrode and the second electrode, the switching layer including at least one chalcogen element selected from sulfur (S), selenium (Se), and tellurium (Te),
wherein at least one of the first electrode or the second electrode includes carbon (C) and, as an additive element, at least one of germanium (Ge), phosphorus (P), or arsenic (As).

2. The switching device according to claim 1, wherein an added amount of the additive element is from 3 at % to 20 at %.

3. The switching device according to claim 1, wherein the switching layer further includes at least one of boron (B) or gallium (Ga).

4. The switching device according to claim 1, wherein at least one of the first electrode or the second electrode has a stack structure of a carbon-containing layer and a metal layer, the carbon-containing layer including carbon (C) and, as the additive element, at least one of germanium (Ge), phosphorus (P), or arsenic (As).

5. The switching device according to claim 4, wherein the carbon-containing layer is provided in contact with the switching layer.

6. The switching device according to claim 4, wherein the carbon-containing layer has a film thickness from 3 nm to 20 nm.

7. The switching device according to claim 1, wherein without involving a phase change between a non-crystalline phase and a crystalline phase, the switching layer is changed into a low-resistance state by increasing an applied voltage to a predetermined threshold voltage or higher, and is changed into a high-resistance state by decreasing the applied voltage to a voltage lower than the threshold voltage.

8. A storage unit comprising
a plurality of memory cells,
the plurality of memory cells each including a memory device and a switching device directly coupled to the memory device,
the switching device including:
a first electrode;
a second electrode disposed to be opposed to the first electrode; and
a switching layer provided between the first electrode and the second electrode, the switching layer including at least one chalcogen element selected from selenium (Se) and sulfur (S),
wherein at least one of the first electrode or the second electrode includes carbon (C) and, as an additive element, at least one of germanium (Ge), phosphorus (P), or arsenic (As).

9. The storage unit according to claim 8, wherein the memory device is any one of a phase-change memory device, a resistive memory device, and a magneto-resistive memory device.

10. The storage unit according to claim 8, wherein the plurality of memory cells includes two or more memory cells that are stacked.

11. A memory system comprising:
a host computer including a processor;
a memory including a memory cell array that includes a plurality of memory cells; and
a memory controller that performs request control on the memory in accordance with a command from the host computer,
the plurality of memory cells each including a memory device and a switching device directly coupled to the memory device,
the switching device including
a first electrode,
a second electrode disposed to be opposed to the first electrode, and
a switching layer provided between the first electrode and the second electrode, the switching layer including at least one chalcogen element selected from sulfur (S), selenium (Se), and tellurium (Te),
wherein at least one of the first electrode or the second electrode includes carbon (C) and, as an additive element, at least one of germanium (Ge), phosphorus (P), or arsenic (As).
